(19) United States
(12) Patent Application Publication
(10) Pub. No.: US 2005/0147749 A1
(43) Pub. Date: Jul. 7, 2005

(54) High-performance vaporizer for liquid-precursor and multi-liquid-precursor vaporization in semiconductor thin film deposition

(75) Inventors: Benjamin Y.H. Liu, North Oaks, MN (US); Yamin Ma, Roseville, MN (US)

Correspondence Address: WESTMAN CHAMPLIN & KELLY, P.A., SUITE 1400 - INTERNATIONAL CENTRE, 900 SECOND AVENUE SOUTH, MINNEAPOLIS, MN, 55402-3319, US

(73) Assignee: MSP CORPORATION, Shoreview, MN (US)

(21) Appl. No.: 10/769,011

(22) Filed: Jan. 30, 2004

Related U.S. Application Data
(60) Provisional application No. 60/534,286, filed on Jan. 5, 2004.

(51) Int. Cl. C23C 16/00

(52) U.S. Cl. 427/248.1; 239/346

(57) ABSTRACT

A vaporization system for thin film formation and for introducing vapors into a deposition chamber for depositing films onto a semi-conductor surface has a vaporization chamber that is selectively provided with at least two different, separate, precursor liquids carried in a gas stream that may be a single carrier gas, or a selected one of a plurality of carrier gasses. When the liquids being introduced are likely to be subject to thermal decomposition from contact with high temperature surfaces, an atomizer is used at the inlet of the vaporization chamber to provide an aerosol to the vaporization chamber from one or more individual sources of liquid combined with one or more individual carrier gasses for simultaneous or sequential introduction into the vaporization chamber. The vaporization chamber may be designed to insure complete vaporization by incorporating a recirculating gas flow through heated passageways before the vaporized gas/vapor mixture exits the vaporization chamber.

The present application is based on and claims the benefit of U.S. provisional patent application Ser. No. 60/534,286, filed Jan. 5, 2004, the content of which is hereby incorporated by reference in its entirety.

### BACKGROUND OF THE INVENTION

The present invention provides a liquid precursor chemical vaporization system in which more than one liquid precursor chemical can be vaporized in one vaporizer, simultaneously or in sequence, and where one or more carrier gasses can be used with one or more cursor chemicals, again, simultaneously or in sequence. The capability for providing a plurality of precursor materials is incorporated into a single vaporizer, resulting in savings in costs and materials, as well as improvement in film quality and wafer throughput in a chemical vapor deposition (CVD) chamber.

When liquid precursor chemicals are used for semiconductor device fabrication, it is generally necessary to vaporize the liquid, which vapor is then introduced into a process chamber containing a semiconductor wafer to form a thin film on the wafer surface. The most commonly used method for thin film formation on a wafer is by chemical vapor deposition (CVD). The CVD process is often used in combination with plasma, which is then referred to as a plasma-enhanced CVD, or a PECVD process. The chamber in which the deposition takes place can be near atmospheric in pressure, i.e. around 760 Torr, or at a reduced pressure, i.e. in a vacuum. The chamber pressure can be in the range of 1 Torr to 760 Torr, in the range above 760 Torr, in the millitorr range, or even in a high vacuum below 1 milliTorr in pressure.

Since many leading-edge liquid precursor chemicals used for semiconductor device fabrication are formulated specially to provide certain specific desirable film properties, they are often quite fragile, and prone to thermal decomposition when heated. A method to avoid thermal decomposition is to atomize the liquid precursor chemical by using a compressed gas to form an aerosol containing precursor droplets, which aerosol is then passed over a heated metal surface to transfer heat to the gas and vaporize the droplets. This avoids, or greatly reduces, direct metal-to-liquid contact, and the consequent thermal decomposition that may take place due to liquid contacting the high-temperature, hot metal surface.

The term aerosol is used herein to refer to atomized liquid droplets or solid particles suspended in a gas. When the desired precursor chemical is a solid, it can be dissolved in a liquid solvent and atomized to form solution droplets. Upon heating of the gas, and the evaporation of the solvent from the solution droplets, the remaining residue of solid particles is suspended in the gas before the solid itself is vaporized, and the gas with the suspended solid, essentially dry particles is also referred to as an aerosol. Thus an aerosol is a gas having either suspended liquid droplets or solid particles. The size of the suspended droplets or solid particles is usually between 1 to 10 μm in diameter, but a gas containing suspended droplets or solid particles as large as 100 μm, or as small as 0.002 μm can still be referred to as an aerosol. Droplets or particles below 0.002 μm are usually referred to as molecular clusters, but for the purpose of this invention a gas carrying any particulate matter below 100 μm in suspension referred to as an aerosol.

A previous invention disclosed in U.S. Pat. No. 6,409,839, which is incorporated by reference, included a system shown in FIG. 1 and a vaporization chamber shown in FIG. 2. Briefly, the system of FIG. 1 provides a carrier gas from a source 12 introduced with a reagent liquid, 14, into an aerosol generator, 16, to form an aerosol, which is then introduced along a line or passageway 18 into a heated vaporization chamber 24 to form a gas/vapor mixture. This mixture of gas and vapor is then filtered through a heated filter 25, to remove particulate contaminants that may remain in the gas phase and thus mixed in with the gas/vapor mixture. The gas/vapor mixture is then introduced into a CVD chamber 26 for film deposition. A controller 28 is used for controlling the flow of heated gas/vapor mixture into the CVD chamber 26 from the heated gas filter 25 through a heated flow restriction 29 and a heated control valve 30. Sensors and flow controllers are used in the system, as detailed in U.S. Pat. No. 6,409,839.

FIG. 2 shows a detailed design of the vaporization chamber 24. The aerosol from generator 16 is introduced into the vaporization chamber through line or passageway 18, and through a multitude of heated passage ways 34 in a block 36 provided with a heater 38 to heat the carrier gas and vaporize the droplets in the aerosol to form the desired heated gas/vapor mixture in an outlet chamber 40.

The heated gas/vapor mixture is then filtered through the heated porous metal or ceramic filter, 25, and then through the heated flow restriction 29 in the form of a coiled capillary tube before it is introduced into the CVD chamber 26 (FIG. 1) through the heated control valve 30. Again, details of construction are included in U.S. Pat. No. 6,409,839. The prior art device described above and similar devices are designed to vaporize a single liquid precursor chemical with the help of a single carrier gas. In applications where more than one liquid precursor chemical is needed, it is necessary to use a plurality of such vaporizers, one for each precursor chemical application. This leads to unnecessary duplication of physical components, cumbersome installation, difficulty in operation, and high cost.

### SUMMARY OF THE INVENTION

The present invention provides a liquid precursor chemical vaporization system having a vaporization chamber in which more than one liquid precursor chemicals can be vaporized simultaneously or in sequence. One or more carrier gases can be used with one or more of the precursor chemicals, again simultaneously or in sequence. The capability is incorporated into a single vaporizer with the selection and sequencing of the precursor and carrier gases can be controlled as desired, this leads to simplification of semiconductor wafer fabrication equipment design, installation, and operation, as well as cost reduction. The invention thus gives rise to savings in materials, cost of construction, installation, maintenance, and more importantly, improvement in film quality, and wafer throughput.

### BRIEF DESCRIPTION OF THE DRAWINGS

FIG. 1 is a block diagram of a prior art arrangement for deposition of a thin film on a semiconductor;

FIG. 2 is a schematic cross sectional view of an aerosol vaporization chamber used in the system of FIG. 1;

FIG. 3 is a block diagram of a vaporization system made according to a first form of the present invention;

FIG. 3A is a schematic representation of the system of FIG. 3 showing the atomizer in greater detail;

FIG. 4 is a block diagram of a vaporization system made according to a second form of the present invention;

FIG. 5 is a schematic block diagram of a further modified form of the present invention;

FIG. 6 is a schematic block diagram of a system similar to FIG. 5 with a modified atomizer;

FIG. 7 is a sectional view of a two stage vaporization chamber useful with the present invention; and

FIG. 8 is a schematic top view of the chamber of FIG. 7 with parts broken away.

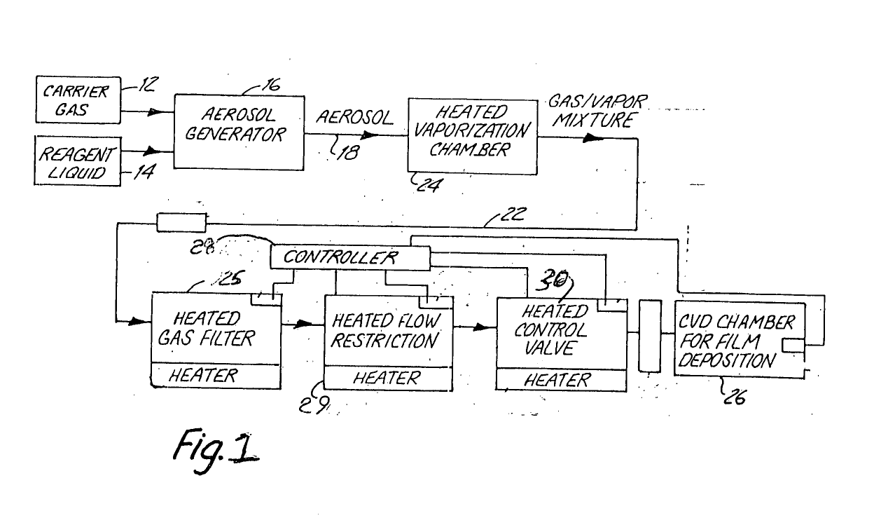

### DETAILED DESCRIPTION OF THE PREFERRED EMBODIMENTS

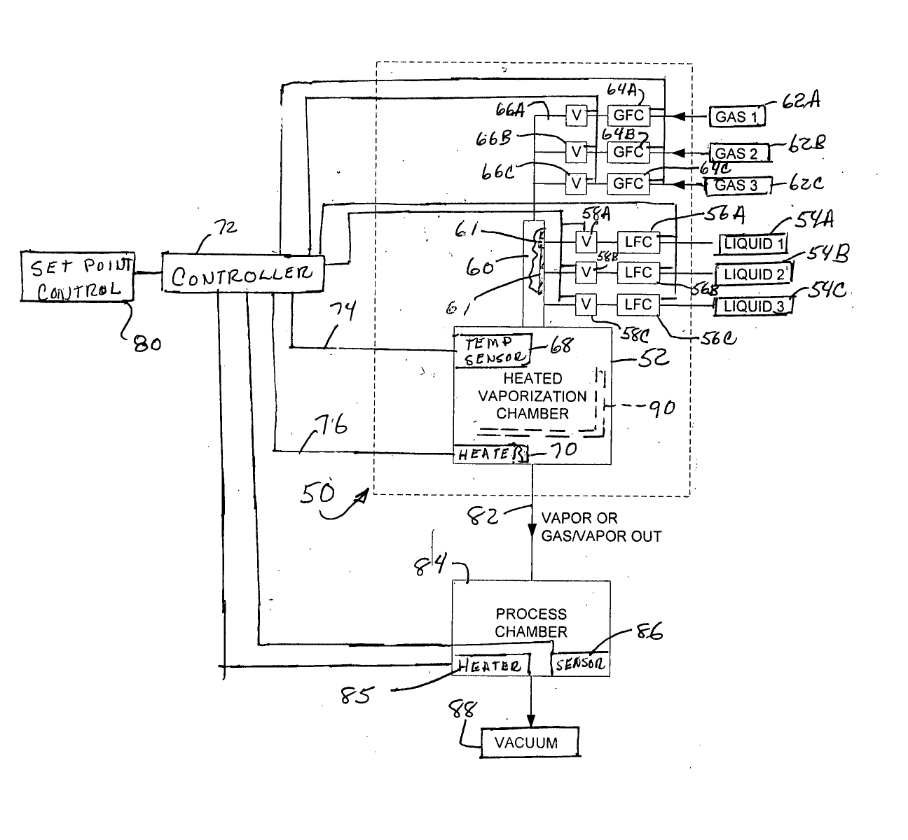

FIG. 3 is a schematic diagram of a multi-liquid precursor chemical vaporization system 50 in one its simplest forms. It includes a single heated vaporization chamber 52 connected to a liquid input source comprising two or more supply sources of different precursors of liquids 54A, 54B, and 54C, each comprising a liquid precursor chemical of the desired chemical nature. Typical liquid precursor chemicals are tetraethyoxisilane (TEOS), and tetraeylborate (TEB), which can be used to make borosilicate glass (BSG) thin films of a low dielectric constant. These chemicals are relatively stable and can be vaporized by direct liquid to metal contact in some applications. The liquid precursor chemicals are usually supplied through individual and separate liquid-flow controllers 56A, 56B, and 56C each being conventionally equipped with a flow sensor to sense the rate of liquid flow, and a flow control valve that can be adjusted or varied to provide the desired liquid flow rate to the vaporizer 52. Also included in the lines from the flow controllers to the vaporizer 52 are positive shut-off valve 58A, 58B, and 58C that can be turned off to stop the liquid flow from the liquid source to the vaporizer 52 when the system is idle or shut down for maintenance or repair, or when only a selected one or two liquid precursors are needed. The output connection of the shut-off valves 58A-58C are connected to one or more vaporizer inlet tubes 60 through nozzles 61.

Also connected to the vaporizer 52 through an inlet tube 60 is a gas source comprising one or more carrier gas supply sources 62A, 62B, and 62C each providing gas to an input tube or tubes 60 through a gas flow controller 64A, 64B, or 64C. The gas flow controllers are conventional units that control the rate of gas flow, from the source in relation to a desired set-point value. Each gas flow line also is equipped with a shut-off valve 66A, 66B, or 66C for positively shutting off the respective gas supply the unit. The inlet tubes introduce the liquid under pressure provided at the supply source for example, through nozzles 61 into a gas from one of the gas supply sources to carry liquid drops into the chamber 52. The nozzles are designed to break the liquid into drops that can be carried along with the gas flow.

The vaporization chamber 52 is also equipped with a temperature sensor 68, and a heater 70 to maintain the chamber interior space at a desired temperature.

The controller 72 can be an analog controller or a micro-processor based digital controller. The controller is connected to receive signals from the temperature sensor 68 along line 74, and will control the heater 70 along line 76 to heat the vaporization chamber to the desired temperature as needed for vaporization. The temperature is adjustable according to the need of the specific liquid precursor that is to be vaporized, and this can be set with any desired type of set point control 80 that would provides an input signal to the controller 72.

The liquid flow controllers and the gas flow controllers shown, generally include an internal flow sensor and an adjustable valve. The signal from each flow sensor produces an output which can be used as an input to an electronic controller to control the flow rate to the desired set-point value. The electronic controller is usually internal to the flow controller. Alternatively, the flow sensor output can be connected to an external controller 72. Controller 72 then in turn is connected to adjust an internal valve in each of the liquid or gas flow controllers, to provide the proper flow rate. The controller 72 is also connected to control the shut off valves 66A-66C and 58A-58C.

The controller 72 can be any desired type of electronic controller. It can be digital, or analog. The controller will sense feedback signals and control outputs for adjusting the flow in the individual valves for the liquid or the gas. For some simple applications, the control can be done manually. In which case, an equivalent manual control can be provided so that an operator will make the necessary manual adjustment to provide the proper flow rates and the temperatures to the vaporizer.

An output opening of the vaporization chamber 52 is connected with a suitable line or passageway 82 to a process chamber 84 that can be used for processing semi-conductor wafers, or the like. The process chamber 84 is a chemical vapor deposition (CVD) chamber and has a heater 85, and a temperature sensor 86, both of which can be connected to the computer controller 72 for controlling the temperature in the process chamber 84. A vacuum source 88 is also connected to the process chamber for providing the desired internal conditions for appropriate processing of semi conductor wafers.

It should be noted that in FIG. 3, the precursor liquid may be fed to the vaporization chamber and vaporized in a conventional manner by direct contact with the hot metal surface of a heated plate 90, without first being atomized to form droplets. Atomization would not be necessary if the liquid precursor is sufficiently stable at the vaporization temperature so it will not thermally decompose. Direct-contact vaporization, rather than atomization-and-vaporization would be an alternative method for multi-liquid precursor vaporization, when stable precursors are used.

In the embodiment of FIG. 3, there is no attempt to atomize the liquid by a high velocity gas. The liquid should be relatively volatile and easy to vaporize. With easily vaporized liquids the arrangement of FIG. 3A can be used with the atomizer using liquid and gas inlets shown in FIG. 3. The liquid and gas aerosol from the atomizer 60 can be introduced into a simple heated vaporization chamber 53A of a housing 53 through a tube 53B. Tube 53B discharges the aerosol near the bottom of the chamber 53A. As the gas and liquid come in contact with the heated metal surface 53C, the gas is heated, and the liquid is vaporized. The gas vapor mixture then flows upwardly and exits from the side to the CVD chamber. The heated chamber 53A does not need to be in form of a cylindrical volume. Various geometrical arrangements can be made to insure that the gas and liquid can be heated properly, and that would be obvious to those skilled in the art of heat exchanger design.

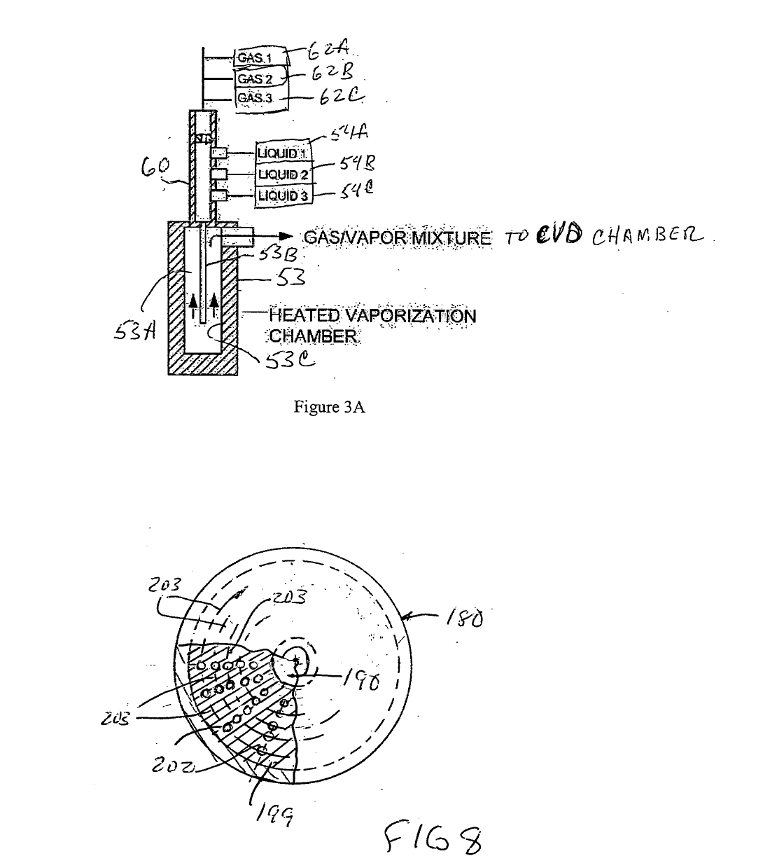

FIG. 4 is a schematic diagram as a second system 92 showing the use of an atomizer 94 for multi-liquid precursor chemical vaporization. This is the preferred form for multi-precursor chemical vaporization. Typical precursor chemicals include tetraethyoxisilane (TEOS), tetraeylborate (TEB), tetramethycyclotetrasiloxane (TOMACTS), triethyloxyphosphine and oxide (TEPO), which can be used in suitable combination in a CVD deposition chamber to deposit phosphosilicate glass (PSG), borosilicate glass (BSG), or boro-phosphosiicate glass (BPSG) thin films of a low dielectric constant (low k dielectrics). The atomizer 94 is shown schematically and has an input line 96 connected to two (or more) gas sources 98A and 98B that are pressurized sources. Each gas source 98A, 98B is connected to the input line 96 through a gas flow controller 100A, 100B and a positive shut-off valve, 102A and 102B, respectively. The plurality of gas sources allows more than one carrier gas to be used with the atomizer 94. The atomizer 94 includes an orifice plate 104, typically with a small diameter orifice opening so that the pressure drop across the orifice can be greater than the critical pressure drop needed to produce a gas flow at sonic velocities for fine droplet atomization.

Downstream of the orifice plate 104 is a gas flow passageway 106 in the atomizer that has two or more liquid input tubes 108A or 108B connected thereto. Each tube 108A, 108B is connected to a separate supply source 110A or 110B of a liquid precursor chemical through a liquid flow controller 112A or 112B and a positive shut-off valve 114A or 114B. When the precursor liquid from one of the sources 110A or 110B is flowing (under pressure from the supply source) into the gas flow passageway 106, it is injected by nozzles and atomized by the high velocity gas jet flowing through the same passageway 106 from orifice plate 104 thereby forming small liquid droplets. The gas and liquid droplet mixture i.e. the aerosol, then flows out of the gas flow passageway into the heated vaporization chamber 116. The liquid pressures, nozzles, sizes and gas flow requirements for atomization are well known.

The flow controllers for the liquid precursor and the carrier gases are conventional and include flow sensors and adjustable valves connected to an electronic controller, which can be internal to the flow controller, or located outside as shown in FIG. 3.

The vaporization chamber 116 is usually electrically heated. The heater 118 provides energy needed to heat a block 120 on the internal cavity 121 of the vaporization chamber 116 to the desired temperature so as to provide the energy needed to heat the carrier gas and vaporize the liquid droplets in the aerosol formed at the atomizer 94. A temperature probe or sensor 122 is provided to sense the temperature. A controller, such as controller 72 similar to that shown in FIG. 3 is used to control the heater to keep the vaporizer block 120 at the set-point value.

The block 120 is provided with a multitude of parallel passageways 124 through which the aerosol can flow and be heated by heat transfer, first to the gas and then to the droplets for vaporization. The parallel passageways 124 reduce the gas velocity through each passageway to allow more time for the gas to be heated and the droplets to vaporize. By this means the gas can be heated more efficiently in a small volume so that the vaporizer can be made more compact for a given rate of gas and liquid flow.

The atomizer 94 shown is especially convenient when two or more liquid precursor chemicals are needed for use with one or more carrier gases. If the same carrier gas can be used with all the liquid precursors, only one carrier gas supply needs to be provided and one gas flow controller and one gas shut-off valve need to be installed.

In operation, when the vaporizer 116 has reached the desired operating temperature, the carrier gas from one or more supply 98A or 98B will be turned on. This can be accomplished by a control signal sent from a computer (similar to controller 72 shown in FIG. 3) to open the shut-off valve 102A or 102B (or both) and a signal to the gas flow controller or controllers will provide gas flow at the desired value. The same controller such as controller 72 shown in FIG. 3 can then send a signal to open the desired liquid shut-off valve 114A or 114B and set the liquid flow rate to the desired set-point value with the liquid flow controller 112A or 112B.

These adjustments can occur simultaneously, or in sequence. For instance, it may be desirable to turn on the gas flow first, and allow a brief time of delay to allow the gas flow to be stabilized before turning on the liquid flow to form a gas/liquid mixture. The gas/liquid mixture or aerosol containing liquid droplets is passed through headed passageway 124 to vaporize the liquid droplets, and then the hot carrier gas vaporized precursors is passed through a heated filter 126 and through an output line or passageway 128 (which may also be heated) for introduction into a process chamber 130 for film deposition.

In the event that the process application calls for the introduction of a mixture of two or more precursor vapors in a carrier gas, the carrier gas flow can be turned on along with both (or the desired number) of the precursor liquid flows. The aerosol from atomizer 94 would thus comprise droplets of two or more precursor liquids suspended and mixed in with the same carrier gas. Upon heating of the gas and vaporization of the precursor liquid droplets as the aerosol passed along passageway 124, the gas/vapor mixture then contains the vapor from the two or more precursor chemicals. This gas mixture can then be delivered to the process chamber 130 for thin film deposition. The high velocity atomizer gas will insure that the droplets are uniformly mixed with the carrier gas and that the gas/vapor mixture will also have a uniform composition both spatially and in time.

If the specific application calls for the delivery of a precursor vapor with its own specific carrier gas, the flows of the specific gas and the specific precursor liquid can be turned on and controlled to provide the proper carrier gas and liquid flow to generate the desired droplet aerosol at the desired rate, and upon heating and vaporization in the vaporization chamber, the proper carrier gas/precursor vapor mixture can thus be generated. This can be followed by a second step where a second set of carrier gas/precursor liquid combination is used to generate a second combination of carrier gas/liquid precursor aerosol, and a second carrier gas and a second vapor mixture following vaporization.

As will be clear to those knowledgeable in semiconductor device fabrication the atomizer and vaporizer arrangement described above will provide a great deal of flexibility for the semiconductor device fabrication plant, also known as the “device fab”, or simply as the “fab”. One carrier gas can be used with two or more liquid precursor supply systems to generate a mixture of gas with two or more precursor vapors that can be introduced into the process chamber to generate a thin film comprising multiple components of chemical species provided by different liquid precursor chemicals. It can also be used to generate different layers of material in sequence by the suitable choice of carrier gas and liquid precursor to achieve the desired film property.

The system of FIG. 4 can be used to generate a thin film, and “dope” the film with the desired chemical species simultaneously or in sequence to generate film with unusual properties or qualities. This approach to liquid precursor chemical vaporization, and the vaporizer constitutes a significant advance, not just in vaporization technology, but in semiconductor device fabrication technology as well. The use of a heated filter 126 in the vaporizer 116 will insure that the gas/vapor mixture leaving the vaporizer 116 is nearly free of particulate contaminants to insure high film quality that is necessary for high product quality and device yield.

The operating pressure of the atomizer, i.e. the absolute pressure upstream of the orifice 104 is typically twice the absolute pressure downstream, so that there is sonic flow through the orifice. For example, if the downstream pressure is 1 atmosphere, or 760 Torr, the upstream pressure would be typically around 2 atmosphere, or around 1500 Torr or higher in absolute pressure. Since the atomizer outlet is connected to the vaporization chamber, the pressure downstream of the atomizer orifice should be similar to the pressure in the chamber. In some cases, the vaporization chamber may need to be operated at a lower pressure, and the pressure upstream of the orifice would also have to be lower. For instance, if the chamber pressure is, say 100 Torr, then the pressure upstream of the orifice should be around 200 to 300 Torr. The pressures are related to insure sonic flow at the orifice.

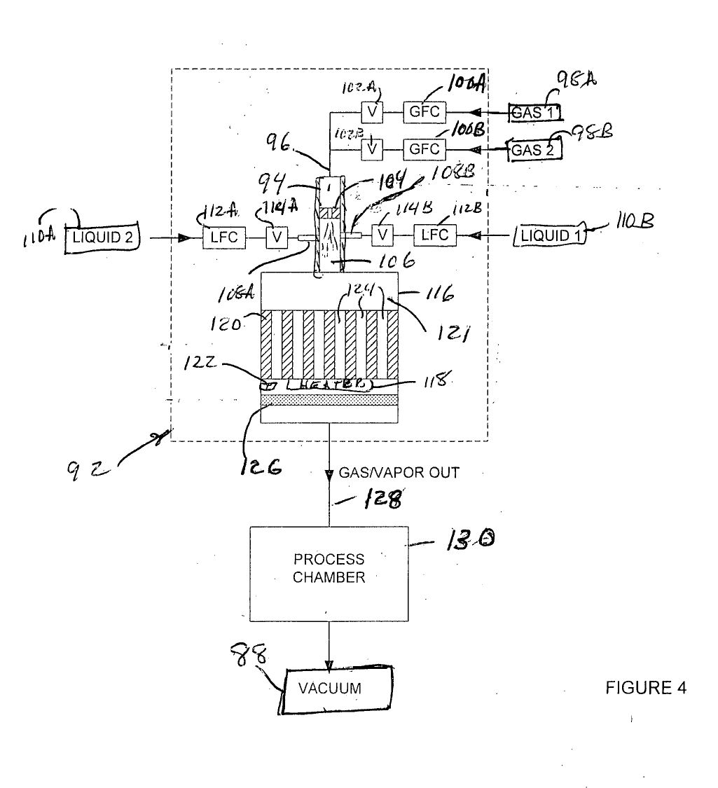

FIG. 5 shows a modified deposition system 92A that has a modified form of the input atomizer to the same vaporization chamber 116 as shown in FIG. 4 for multi-liquid precursor liquid vaporization. As shown in FIG. 5, the same arrangement as FIG. 4 is disclosed except that separate atomizers 142A and 142B are built into the same atomizer head 140. Only two atomizer passageways are shown for clarity.

Each atomizer 142A and 142B is provided with one source of gas 98A, 98B, controlled by a separate gas flow controller 100A, 100B and a separate positive shut-off valve 102A, 102B, respectively. Each atomizer has an orifice plate 144A or 144B, respectively. Similarly, the liquid supply tube 108A or 108B opens into a separate chamber 146A and 146B forming output chambers, or passageway of the atomizers 142A and 142B. Each atomizer is thus provided with one source of liquid precursor from source 110A or 110B, one liquid flow controller 112A or 112B, and a positive shut-off valve 114A, 114B.

Additional atomizer passageways and orifice plates of substantially the same design can be incorporated into the same atomizer head. The number of atomizer passageways that can be incorporated into a single atomizer head for droplet precursor chemical vaporization is limited only by space requirements, and by the number of precursor liquids that need to be vaporized in a single piece of equipment in a specific installation.

The advantage of the vaporizer design in FIG. 5 compared to that shown in FIGS. 3 and 4 is that each liquid flow in FIG. 5 is confined in its own liquid flow passageway in the atomizer and into an inlet to the vaporization chamber. The different liquids will thus not mix, or come into contact with each other before they are atomized to form a separate droplet aerosol for vaporization. In some situations, mixing of precursor liquid chemicals may be undesirable and needs to be avoided. The disadvantage of the apparatus based on the design in FIG. 5 is that separate atomizing gas flows are used to atomize different liquids, so the mass concentration of the droplet aerosol in the carrier gas is lower than the designs shown in FIGS. 3 and 4. In the latter cases, the same atomizing gas is used to atomize two or more liquid precursor droplets. The mass concentration of the droplet aerosol in the carrier gas can thus be lower with the multiple atomizers of FIG. 5.

In some applications, the precursor liquid may have a high molecular weight that may be in excess of 300 or more. Some of these precursor liquids may also have a high viscosity, making it difficult to atomize to form droplets. Since the viscosity of most, if not all, substances decreases with increasing temperature, the liquid may be heated to a higher temperature for ease of atomization.

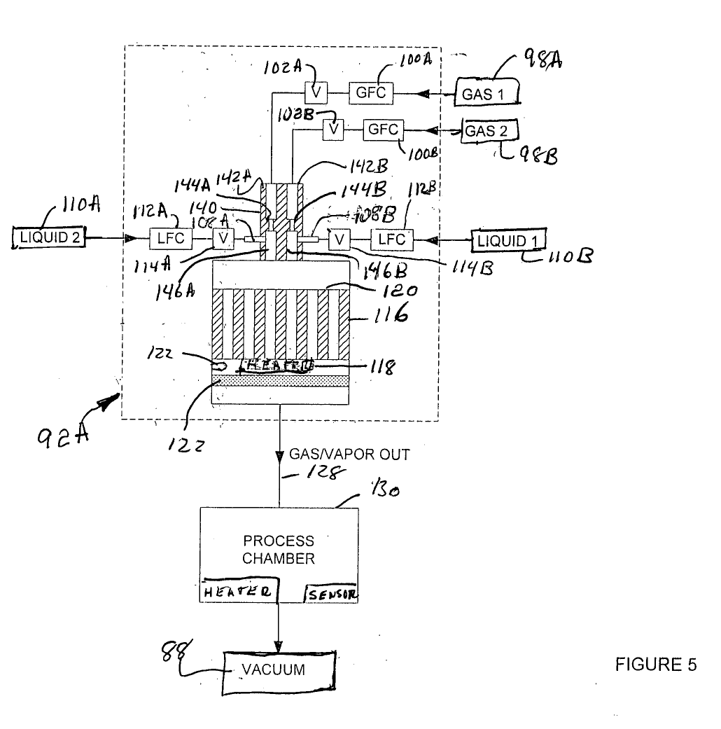

In FIG. 6, a system 92B includes a heater 150 in the supply line for the precursor liquid from source 110B, which for illustrative purposes, is assumed to have a high viscosity. Heaters can be used in the supply lines of all precursor liquids, if desired. By heating the precursor liquid to a suitably high temperature, the liquid viscosity can be reduced, thereby making it easy to atomize. However, it is important that the heating is not excessive to cause thermal decomposition.

A modified atomizer head 152 has two atomizers 154A and 154B that can be applied to a wider range of liquids, including those that cannot be easily atomized at room temperature. The atomizer head 152 is provided with a mounting flange 156 that is insulated from the vaporization chamber 116 with a layer of insulation 158 to prevent the atomizer head 152 and the liquid precursor in contact with the head from being over-heated by the high temperature used for droplet vaporization in the vaporization chamber 116. If the insulation layer 158 is inadequate to keep the atomizer head 152 sufficiently cool, a stream of cooling gas from a source 160 can be directed through passageways 162 in the atomizer head 152 to keep the atomizer head at a moderate to low temperature. In some instances, it may be necessary to use a liquid coolant from a source to keep the atomizer head temperature in a reasonable operating range.

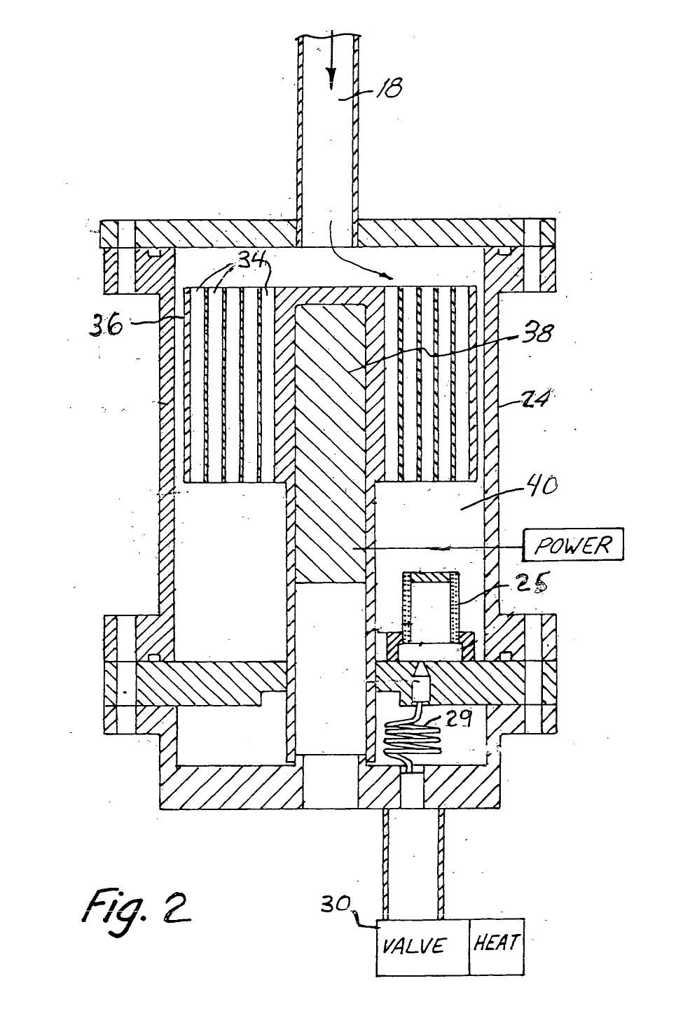

As explained earlier, FIG. 2 is a schematic diagram of the vaporizer shown in the previous invention disclosed in U.S. Pat. No. 6,409,839. This prior art vaporizer is further improved in the current invention.

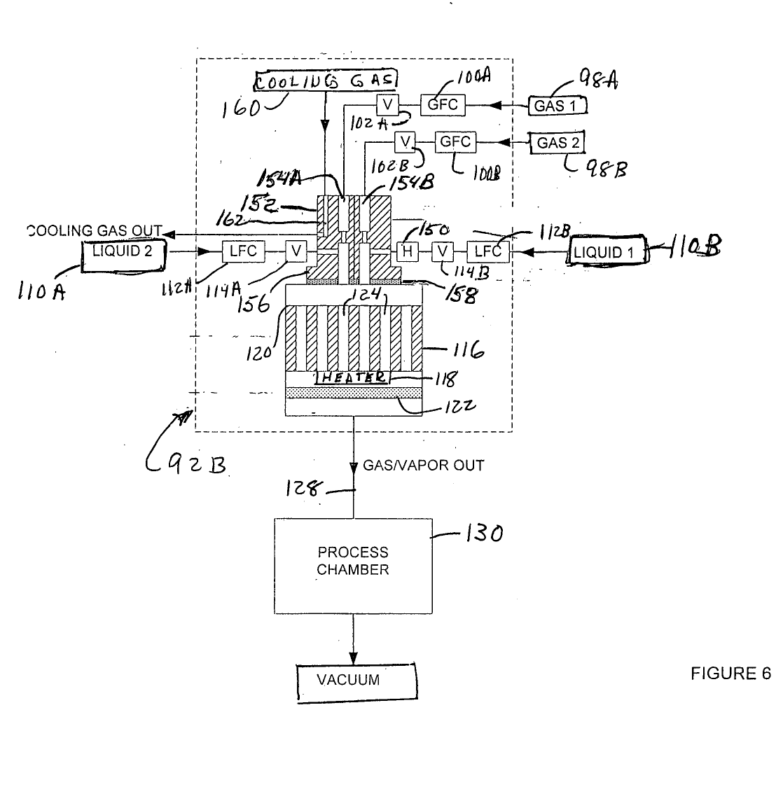

FIG. 7 is a schematic diagram of a modified form of the invention including an improved vaporizer 180. An atomizer 182 is used to form a droplet aerosol containing the desired precursor liquid chemicals. One gas source 184 and one liquid source 186 are shown for clarity, but it is understood that the atomizer 182 can be designed to include more than one gas source and more than one liquid source. The atomizer includes an orifice 188 through which the gas discharges as shown previously and has an outlet 189. The output flow from the atomizer 182 would thus contain one or more than one liquid source chemicals in droplet form. As this aerosol leaves the atomizer 182 it is in the form of a high velocity aerosol jet represented by arrow 190. As this jet of gas containing suspended droplets enters the heated vaporization chamber 192, it is heated in a suitable manner with a heater represented schematically at 194. The aerosol mixes with the heated gas to form a heated aerosol jet. Small droplets will evaporate quickly in this heated gas mixture, larger droplets will evaporate more slowly and may contain some partially vaporized droplets. The result is a heated gas mixture containing vapor and some partially vaporized droplets. This heated gas mixture, due to the momentum conservation principle in gas flow, will continue to travel at a relatively high velocity for a considerable distance. This high velocity heated aerosol stream is then directed at a mixing orifice 196 and into a cylindrical passageway 198 formed in a heated metal block 199 downstream of the orifice 196. The orifice 196 is substantially the same size as, or can be smaller than the passageway 198.

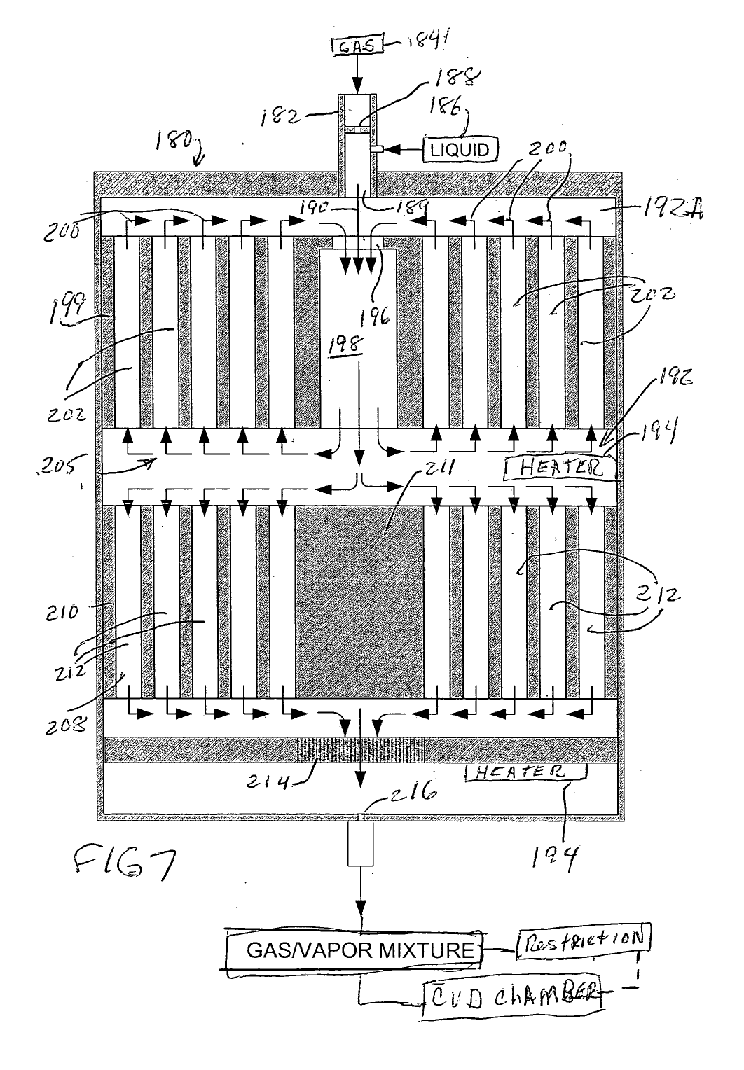

As the heated aerosol stream flows through the mixing orifice 196, carrying with it the entrained heated gas from the vaporization chamber, a negative pressure is created in the upper part 192A of the vaporization chamber 192. This negative pressure sets up a continuous re-circulating gas flow as depicted by the arrows 200 showing the direction of the re-circulating gas flow. As this re-circulating gas flows upward through the individual small cylindrical passageways 202 arranged on annular lines 203 concentric with and surrounding the central large tubular passageway 198, (see FIG. 8) the gas flow in each passageway 202 is at a relatively low value and flowing at a relatively low gas low velocity. Any unvaporized droplets in the re-circulating gas flow entering each cylindrical passageway from the bottom of the heated metal block 199 will thus spend considerable amount of time in the small cylindrical passageway. As each gas stream emerges from the exit on the top of the block 199 and into the upper part 192A of the chamber 192, droplets contained in the gas stream when the gas stream first entered the chamber 192 from the atomizer would be completely evaporated. By choosing the proper mixing orifice size, and the distance between the orifice 196 and the atomizer outlet 189, a high volume re-circulating gas flow can be established. Re-circulating gas flow as high as ten times or more of the gas flow at the atomizer outlet 189 can be easily maintained this way, without the use of a pump, or other devices involving moving mechanical parts.

The re-circulating gas-flow vaporizer 180 described above forms a Stage one 205 of a two stage and improved vaporization system depicted in FIG. 7. Stage two 208 of the vaporization system comprises a cylindrical metal block 210 in a lower portion 192B of chamber 192 having numerous cylindrical flow passageways 212 in the cylindrical metal block 210, similar to those in Stage one. The heated gas flow at the outlet 198A of the central tubular passageway 198 is above an imperforate surface of a center plug 211 of the block 210. Gas flow at the outlet 198A that is not re-circulated is directed through the passageways 212 of the Stage two vaporizer block 210 to fully vaporize the droplets before the gas stream passes through a heated filter 214 located downstream of block 210. Any un-vaporized droplets flowing through the filter 214 will cause the filter to become clogged. The second vaporization stage 208 will insure that this does not happen and that the droplets are completely vaporized and no droplets would remain even at a comparatively low vaporization temperature, to minimize the possibility of material decomposition. The gas/vapor mixture flows from an outlet 216 and can then enter a CVD chamber (as shown in FIG. 4) located downstream, either directly, if the CVD chamber can be operated at the same pressure as the vaporizer, or through a flow restriction, which can be in the form of an orifice, a length of small diameter capillary tube, etc. before the gas/vapor mixture is introduced into the CVD chamber operating at a lower pressure than the vaporizer. The flow from the inlet 189 to the outlet 216 of the chamber 192 follows a flow direction or flow path axis in the vaporization chamber.

### Applications

There are wide varieties of applications where the improved vaporizer system and the multi-liquid precursor vaporization system described in this specification can be used. Particularly important are insulating thin films of a low or a high dielectric-constant, also referred to as low-k or high-k dielectrics. These films are used as insulating layers in semiconductor device fabrication on a silicon wafer. Simple silicon dioxide (SiO₂) thin films of a low dielectric constant can be made using a single precursor chemical such as Tetraethyloxisilane (TEOS) or Tetramethyclotetrasiloxane (TOMACTS). Tatalum pentoxide (Ta₂O₅) thin films of a high dielectric constant can also be made using a single precursor chemicals such as tantalum tetraeoxydimethyaminoethoxide (TAT-DMAE). Silicon nitride (Si₃N₄) thin films, also of a high dielectric constant, can be made by the LPCVD process using the precursor chemical Bis(terbutylamino) silane (BTBAS). Thin glass films constaining the elements silicon, boron, and/or phosphorous can be made by a CVD process using suitable precursor chemicals containing these elements. Common precursor chemicals include Tetraethyloxisilane (TEOS), Tetraethylborate (TEB), and Triethyloxyphosphine oxide (TEPO), which can be used in a suitable combination to make thin films of boro-silicate glass (BSG), phosphor-silicate glass (PSG), or boro-phospho silicate glass (BPSG). Other liquid precursor chemicals are constantly being developed. Some will require the vaporization of one single precursor chemical. Others will require two or more precursor liquid chemicals to be vaporized. To have a method and device that can be used to vaporize multiple liquid precursors in the same apparatus will lead to saving in cost of the equipment, and provide a degree of control that is hither-to-fore impossible for semiconductor thin film deposition.

Instead of having holes through the metal blocks shown, the heat conductive metal blocks can be made of a heat conductive porous material. The porous material will form passageways for allowing heat to transfer to the gas/vapor mixture flowing therethrough.

Although the present invention has been described with reference to preferred embodiments, workers skilled in the art will recognize that changes may be made in form and detail without departing from the spirit and scope of the invention.

1. An atomizer having a gas flow inlet, and an aerosol outlet, a source of gas connected to the gas flow inlet, an orifice forming a gas jet between the inlet and the outlet, and a source of liquid to be atomized connected to be introduced in the gas jet, at least one of the sources comprising a plurality of different gas or liquid respectively, selectively provided to the atomizer.

2. The atomizer of claim 1 wherein the source providing a plurality of different gas or liquid comprises a source of gas connected to the gas flow inlet of the atomizer, and having a plurality of different types of gas introduceable into the inlet.

3. The atomizer of claim 1 wherein the source comprising a plurality of different gas or liquid material is the source of liquid, and a plurality of different liquids selectively introduceable into the atomizer.

4. The atomizer of claim 1 wherein the atomizer has a plurality of passageways defined therein, the source having a plurality of gas or liquid comprising a plurality of gas sources, and each gas source connected to a separate passageway, and wherein the source of liquid comprises a plurality of different types of liquid, each source of the different types of liquid being connected to a selected one of the passageways of the atomizer.

5. The atomizer of claim 1 wherein each of the sources has a flow controller between the source and the atomizer.

6. The atomizer of claim 1, wherein both of the sources comprise a plurality of gas or liquid materials from the respective sources.

7. A vaporization system for vaporizing materials carried in a gas stream comprising an outer housing defining a vaporization chamber, a heated surface member in the chamber, a first source of at least one gas connected to the chamber, a second source of at least one liquid to be carried in the gas and into the chamber, wherein at least one of the first and second sources comprises a plurality of different materials consisting of one of the respective gas and liquid for introduction into the chamber to be vaporized therein from heat on the heated surface member.

8. The vaporization system of claim 7 wherein the first and second sources are connected through an atomizer to the vaporization chamber.

9. The vaporization system of claim 7 wherein the vaporization chamber has an inlet, the first and second sources being connected to the inlet in a manner such that the gas from the first source will engage liquid from the second source as the gas moves toward the inlet to the vaporization chamber.

10. The vaporization system of claim 7 wherein the inlet is connected to an outlet of an atomizer, said first and second sources being connected to the atomizer to cause atomization of liquid from the second source in a gas from the first source.

11. The atomization system of claim 7 including a controller for controlling flow of materials from the first and second sources, and controlling the heat on the heated surface member in the vaporization chamber.

12. The vaporization system of claim 10, wherein the vaporization chamber has an outlet, and wherein a chemical vapor deposition chamber is combined with the vaporization chamber, the outlet of the vaporization chamber being connected to an inlet of the chemical vapor deposition chamber.

13. The vaporization system of claim 12, wherein the atomizer comprises a plurality of passageways therethrough, each of the passageways being connected to receive a different gas from the first source, and where each passageway in the atomizer forms a gas jet, and a connection to receive separate liquid from the second source into a flow path subsequent to the formation of the gas jet, and the outlet of the atomizer being connected to the inlet of the chemical vapor deposition chamber.

14. The vaporization system of claim 7, wherein each of the first and second sources have a flow controller controlling flow from the respective source to the vaporization chamber.

15. The vaporization system of claim 14, wherein there is a separate shut off valve between each flow controller and the vaporization chamber.

16. A chemical vapor deposition system comprising a chemical vapor deposition chamber having an inlet, and a source of deposition materials for forming thin films on wafers in the chemical vapor deposition chamber comprising a vaporization chamber connected to the inlet of the chemical vapor deposition chamber, said vaporization chamber having a heated surface portion, and a first source of a gas for introduction into the vaporization chamber through a connecting passageway, said first source having a plurality of different gaseous materials selectively introduced into the passageway to form a flow of gas, and a second source of liquid material forming a source of at least one precursor liquid chemical for deposition in the chemical vapor deposition chamber connected to the passageway in a flow path subsequent introduction of the flow of gas through the passageway, whereby droplets of at least one liquid are mixed with the gas prior to introduction into the vaporization chamber.

17. The system of claim 16, wherein the inlet to the vaporization chamber is connected to an outlet of an atomizer, the first and second sources being connected to the atomizer such that a plurality of different liquids can be selectively atomized sequentially or simultaneously and introduced into the vaporization chamber.

18. The system of claim 17, wherein the atomizer has individual atomizer passageways in a single atomizer head, each passageway being connected to one of a plurality of gasses the first source, and one of a plurality of liquids from the second source.

19. A method of providing vaporized liquids to a process chamber comprising the steps of providing a vaporization chamber having a heated surface portion therein, providing at least two separate sources of liquid for introduction into an inlet of the vaporization chamber, selectively controlling the flow of liquid from one or more source to the inlet, and mixing the selected liquid with a carrier gas prior to introduction of the liquid and gas into the vaporization chamber.

20. The method of claim 19, including forming a gas jet from the gas, and introducing droplets of liquid into the gas jet to form an aerosol prior to introduction of the liquid into the vaporization chamber.

21. The method of claim 20, wherein forming of the gas jet comprises forming the gas jet in an atomizer arrangement, and providing at least two liquids selectively in sequence or simultaneously to the atomizer arrangement for atomization prior to introduction into the vaporization chamber.

22. A vaporizer for an aerosol comprising a gas and liquid droplets, said vaporizer including a housing defining an interior vaporization chamber having an inlet and an outlet, a first metal block having a plurality of passageways therethrough, a bore through the first metal block aligned with the inlet, through which the aerosol is discharged, and an orifice in the first metal block directly aligned with the inlet, said orifice forming an opening leading to the bore in the first metal block.

23. The vaporizer of claim 22, wherein the orifice is no greater in size than substantially the same size as the bore.

24. The vaporizer of claim 23 wherein the aerosol forms a gas jet through the inlet.

25. The vaporizer of claim 24 wherein the orifice comprises a mixing orifice, and the velocity of the gas jet causes a recirculation from an output side of the bore of the first metal block through the plurality of passageways in the first metal block back toward the inlet for mixing with the aerosol as the aerosol passes through the mixing orifice.

26. The vaporizer of claim 22 wherein there is a second metal block in the interior vaporization chamber having a plurality of passageways therethrough, the second metal block being spaced from the first metal block and positioned between the first metal block and the outlet of the vaporizer.

27. The vaporizer of claim 26 wherein the second metal block has an imperforate surface aligned with the bore in the first metal block to divert gas striking the imperforate surface laterally outwardly toward the passageways in the seocnd metal block.
